(19) United States
(12) Patent Application Publication
(10) Pub. No.: US 2018/0286714 A1
(43) Pub. Date: Oct. 4, 2018

(54) COB DIE BONDING AND WIRE BONDING SYSTEM AND METHOD

(71) Applicant: SOUTH CHINA NORMAL UNIVERSITY, Guangdong (CN)

(72) Inventors: Miao HE, Guangdong (CN); Yuanyuan ZHANG, Guangdong (CN)

(21) Appl. No.: 15/531,997

(22) PCT Filed: Dec. 21, 2015
(86) PCT No.: PCT/CN2015/097990

§ 371 Date: May 31, 2017

(30) Foreign Application Priority Data
Dec. 9, 2015 (CN) 201510908357.4

(51) Int. Cl. H01L 21/67; H01L 21/677; H01L 23/00; G06F 17/50

(52) U.S. Cl. CPC H01L 21/67138; H01L 21/67721; H01L 25/0753; H01L 24/48; G06F 17/5072; H01L 24/85

(57) ABSTRACT

Disclosed is a COB die bonding and wire bonding system and method. The system comprises a controller, a forward die bonder, a reverse die bonder and a conveyor belt, the controller being connected with the forward die bonder and the reverse die bonder respectively, and the forward die bonder is associated with the reverse die bonder by the conveyor belt. The system and method can realize the combination of the forward and reverse bonding when using the forward die bonder and the reverse die bonder to fix the chips, thus the amount of gold wire used for connecting chips on a substrate is minimized. The COB die bonding and wire bonding system and method can be widely used in the field of electronics.

### FIELD OF THE INVENTION

The present invention relates to the field of electronics, and especially to a COB die bonding and wire bonding system and method.

### BACKGROUND OF THE INVENTION

COB (Chips on Board), i.e., a technology that a bare chip is adhered to an interconnected substrate with a conductive or non-conductive adhesive, and then its electrical connection is achieved by wire bonding.

Since one die bonder is used during the traditional die bonding operation, only die bonding in the same direction can be achieved, and the wire can only be bonded according to the positive and negative poles in sequence. As most COB substrates are circular, a folded wire bonding mode is formed, as shown in FIG. 3, and the consumption of gold wire is large in actual production. Due to the high cost of gold wire, increase of cost is caused.

### SUMMARY OF THE INVENTION

In order to solve the above-mentioned technical problem, an object of the invention is to provide a COB die bonding and wire bonding device that can save the amount of gold wire used and the time for wire bonding.

In order to solve the above-mentioned technical problem, another object of the invention is to provide a COB die bonding and wire bonding method that can save the amount of gold wire used and the time for wire bonding.

The technical solution adopted in the invention is: a COB die bonding and wire bonding system, comprising a controller, a forward die bonder, a reverse die bonder and a conveyor belt, the controller being connected with the forward die bonder and the reverse die bonder respectively, and the forward die bonder is associated with the reverse die bonder by the conveyor belt.

Further, the controller includes a shortest wire bonding path calculation module which is used to calculate a die bonding layout of chips to achieve the shortest wire bonding path on a substrate.

Further, the shortest wire bonding path calculation module is used to calculate a die bonding layout of chips which can achieve the shortest wire bonding path on a substrate according to the forward die bonding and the reverse die bonding for chips.

Further, the COB die bonding and wire bonding system further comprises a wire bonding device which is connected with the controller.

Another technical solution adopted by the invention is: a COB die bonding and wire bonding method, comprising the following steps:

A. Calculating a die bonding layout of chips which can achieve the shortest wire bonding path on a substrate according to the forward die bonding and the reverse die bonding for the chips;

B. Sending the forward die bonding layout in the above die bonding layout of chips to the forward die bonder, while sending the reverse die bonding layout in the above die bonding layout of chips to the reverse die bonder, and sending the shortest wire bonding path to the wire bonding device;

C. Performing die bonding on the substrate by the forward die bonder, transporting the forward die bonded substrate to the reverse die bonder by the conveyor belt, then performing die bonding on the substrate by the reverse die bonder; and

D. Performing wire bonding to the chips on the substrate by the wire bonding device.

Further, in the die bonding layout of chips which can achieve the shortest wire bonding path in step A, the chips are arranged in rows, wherein the chips in each row are arranged forwardly or reversely, and two adjacent rows of chips are arranged in opposite directions.

Further, in step A of calculating the die bonding layout of chips which can achieve the shortest wire bonding path on the substrate, a Dijkstra algorithm, a SPFA algorithm, a Bellman-Ford algorithm or a Floyd-Warshall algorithm is used.

Further, the die bonding by the reverse die bonder precedes that by the forward die bonder in step C, and the specific description is as follows: performing die bonding on the substrate by the reverse die bonder, transporting the reverse die bonded substrate to the forward die bonder by the conveyor belt, and then performing die bonding on the substrate by the forward die bonder.

One beneficial effect of the invention is that the device of the invention realizes the combination of the forward and reverse bonding when using the forward die bonder and the reverse die bonder to fix the chips, thus the amount of gold wire used for connecting the chips on the substrate is minimized, which in turn saves the cost of electric circuit, working time and labor force.

Another beneficial effect of the invention is that the method of the invention realizes the combination of the forward and reverse bonding when using the forward die bonder and the reverse die bonder to fix the chips, thus the amount of gold wire used for connecting chips on the substrate is minimized, which in turn saves the cost of electric circuit, working time and labor force.

### BRIEF DESCRIPTION OF THE DRAWINGS

FIG. 1 shows a structural schematic diagram of the device of the invention;

FIG. 2 shows a flow chart of steps of the method of the invention;

FIG. 3 shows a die bonding layout way in the prior art;

FIG. 4 shows a schematic diagram of one embodiment of die bonding and wire bonding realized by the device and the method of the invention; and

FIG. 5 shows a schematic diagram of another embodiment of die bonding and wire bonding realized by the device and the method of the invention.

### DETAILED DESCRIPTION OF THE EMBODIMENTS

The specific embodiments of the invention will be further illustrated below with reference to the accompanying drawings.

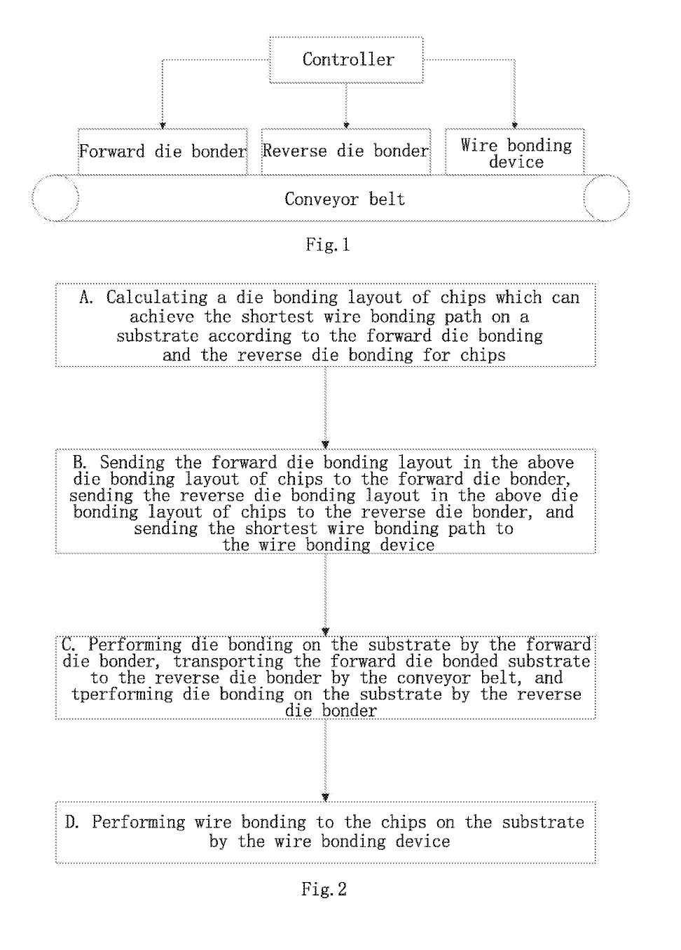

With reference to FIG. 1, a COB die bonding and wire bonding system, comprising a controller, a forward die bonder, a reverse die bonder and a conveyor belt, wherein the controller is connected with the forward die bonder and the reverse die bonder respectively, and the forward die bonder is associated with the reverse die bonder by the conveyor belt.

In a further preferred embodiment, the controller includes a shortest wire bonding path calculation module which is used to calculate a die bonding layout of chips to achieve the shortest wire bonding path on a substrate.

In a further preferred embodiment, the shortest wire bonding path calculation module is used to calculate a die bonding layout of chips, which can achieve the shortest wire bonding path on a substrate, according to the forward die bonding and the reverse die bonding for chips.

In a further preferred embodiment, the COB die bonding and wire bonding system further comprises a wire bonding device which is connected with the controller.

With reference to FIG. 2, a COB die bonding and wire bonding method, comprising the following steps:

A. Calculating a die bonding layout of chips which can achieve the shortest wire bonding path on a substrate according to the forward die bonding and the reverse die bonding for chips;

B. Sending the forward die bonding layout in the above die bonding layout of chips to the forward die bonder, while sending the reverse die bonding layout in the above die bonding layout of chips to the reverse die bonder, and sending the shortest wire bonding path to the wire bonding device;

C. Performing die bonding on a substrate by the forward die bonder, transporting the forward die bonded substrate to the reverse die bonder by the conveyor belt, and then performing die bonding on the substrate by the reverse die bonder; and

D. Performing wire bonding to the chips on the substrate by the wire bonding device.

In a further preferred embodiment, in the die bonding layout of chips which can achieve the shortest wire bonding path in step A, the chips are arranged in rows, wherein the chips in each row are arranged forwardly or reversely, and two adjacent rows of chips are arranged in opposite directions.

In a further preferred embodiment, in step A of calculating the die bonding layout of chips which achieves the shortest wire bonding path on the substrate, a Dijkstra algorithm, a SPFA algorithm, a Bellman-Ford algorithm or a Floyd-Warshall algorithm is adopted.

When the above algorithm is adopted, the forward die bonding and the reverse die bonding for chips in step A are constraint conditions for guaranteeing that there are only the above two die bonding ways for chips, which can be accomplished by the forward/reverse die bonders.

In a further preferred embodiment, in step C, the die bonding operation by a reverse die bonder precedes that by the forward die bonder, and the specific description is as follows: performing die bonding on the substrate by the reverse die bonder, transporting the reverse die bonded substrate to the forward die bonder by the conveyor belt, and then performing die bonding operation on the substrate by the forward die bonder.

With reference to FIG. 4, in the first specific embodiment of the invention, die bonding and wire bonding are performed in different directions, with positive poles of a part of chips facing towards pins of negative poles of the substrate (i.e., “-” in the Figures).

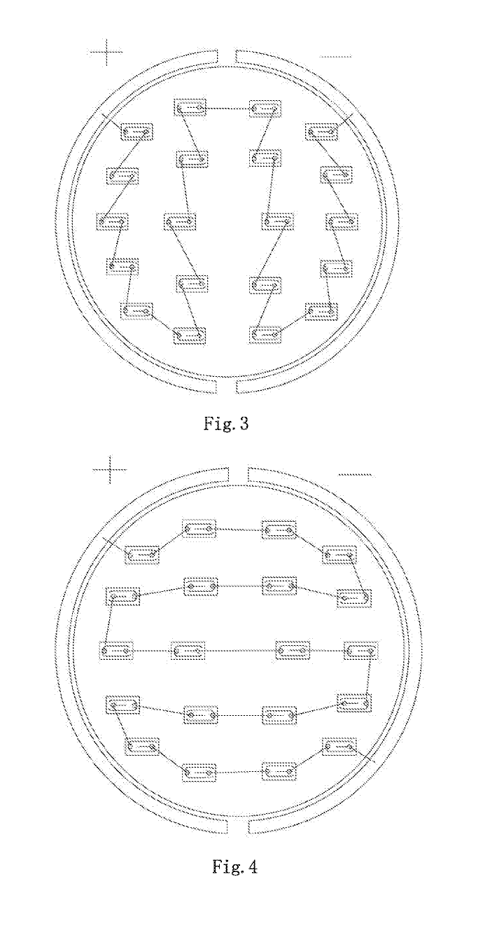

Compared with FIG. 4, FIG. 3 is a die bonding and wire bonding diagram realized by the traditional medium and small power die bonding and wire bonding ways, wherein all the chips are in the same direction, i.e., the positive poles of all chips face towards the pins of the positive poles of the substrate while the negative poles face towards the pins of the negative poles of a substrate when performing die bonding.

In the embodiment of the method as shown in FIG. 4, die bonding is performed in two directions, which saves a large amount of gold wire as compared with the traditional die bonding and wire bonding method in the same direction. It is found through measurement and calculation that the traditional die bonding in the same direction as shown in FIG. 3 requires 0.0525 m/pcs of gold wire, while the method of the invention requires 0.039 m/pcs of gold wire, which saves 25.7% of gold wire, thus significantly reduces the cost.

Meanwhile, as the die bonder performs die bonding after identifying the chips according to their characteristics, the chips can only be bonded in one direction. A repeated setting of parameters will undoubtedly increase labor costs. The new implementation method can be achieved with a system composed of two die bonders, with the first die bonder fixing the chips in the forward direction, the second die bonder fixing the chips in the reverse direction, and the middle section being connected through the automatic conveyor belt, thereby saving the implementation time and cost.

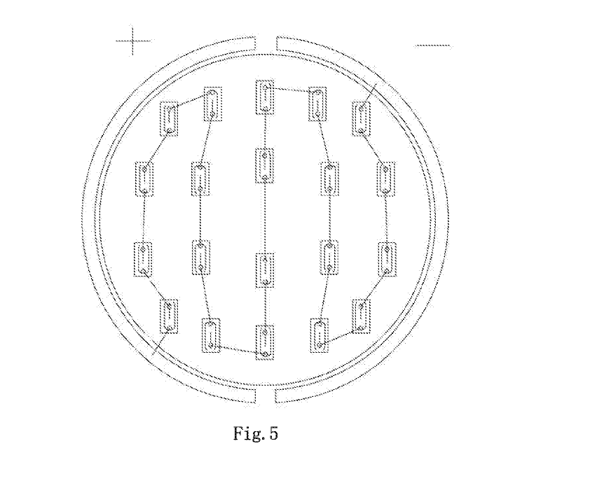

With reference to FIG. 5, as the second embodiment of the invention, with respect to the chips arranged horizontally as shown in FIG. 4, the chips shown in FIG. 5 are arranged in a vertical direction, wherein the chips in each column are in forward or reverse arrangement, and two adjacent rows of chips are arranged in opposite directions. This die bonding layout of chips requires the same amount of gold wire as used in FIG. 4, which can likewise act to save gold wire.

While the preferred embodiments of the invention have been specifically described above, the invention is not limited thereto. Various equivalent variations and substitutions may be made by those skilled in the art without departing from the spirit of the invention and should be included within the scope defined by the claims of this application.

1. A COB die bonding and wire bonding system, comprising a controller, a forward die bonder, a reverse die bonder and a conveyor belt, wherein the controller is connected with the forward die bonder and the reverse die bonder respectively, and the forward die bonder is associated with the reverse die bonder by the conveyor belt.

2. The COB die bonding and wire bonding system according to claim 1, wherein the controller comprises a shortest wire bonding path calculation module for calculating a die bonding layout of chips to achieve the shortest wire bonding path on a substrate.

3. The COB die bonding and wire bonding system according to claim 2, wherein the shortest wire bonding path calculation module is used to calculate a die bonding layout of chips which can achieve the shortest wire bonding path on the substrate according to the forward die bonding and the reverse die bonding for chips.

4. The COB die bonding and wire bonding system according to claim 1, further comprises a wire bonding device which is connected with the controller.

5. A COB die bonding and wire bonding method, comprising the following steps:
a) Calculating a die bonding layout of chips which can achieve the shortest wire bonding path on a substrate according to the forward die bonding and the reverse die bonding for chips;
b) Sending the forward die bonding layout in the above die bonding layout of chips to the forward die bonder, while sending the reverse die bonding layout in the above die bonding layout of chips to the reverse die bonder, and sending the shortest wire bonding path to the wire bonding device;
c) Performing die bonding on the substrate by the forward die bonder, transporting the forward die bonded substrate to the reverse die bonder by the conveyor belt, and then performing die bonding on the substrate by the reverse die bonder, or
Performing die bonding on the substrate by the reverse die bonder, transporting the reverse die bonded substrate to the reverse die bonder by the conveyor belt, and then performing die bonding on the substrate by the forward die bonder; and
c) Performing wire bonding to the chips on the substrate by the wire bonding device.

6. The COB die bonding and wire bonding method according to claim 5, wherein, in the die bonding layout of chips which can achieve the shortest wire bonding path in step A, the chips are arranged in two rows, and wherein the chips in each row are arranged forwardly or reversely, and two adjacent rows of chips are arranged in opposite directions.

7. The COB die bonding and wire bonding method according to claim 5, wherein, in the step A of calculating the die bonding layout of chips which can achieve the shortest wire bonding path on a substrate, a Dijkstra algorithm, a SPFA algorithm, a Bellman-Ford algorithm or a Floyd-Warshall algorithm is used.

8. (canceled)

9. The COB die bonding and wire bonding system according to claim 2, further comprises a wire bonding device which is connected with the controller.

10. The COB die bonding and wire bonding system according to claim 3, further comprises a wire bonding device which is connected with the controller.
